(19) United States
(12) Patent Application Publication
(10) Pub. No.: US 2026/0358410 A1
(43) Pub. Date: Nov. 12, 2026

(54) SUPPORT DEVICE FOR TEST SYSTEM WITH FIXED AND INSULATED SENSE CONTACT

(71) Applicant: Infineon Technologies AG, Neubiberg (DE)

(72) Inventors: Johannes Georg Ploner, Magdalen (AT); Adrian PISNIG, Arnoldstein (AT)

(73) Assignee: Infineon Technologies AG, Neubiberg (DE)

(21) Appl. No.: 19/657,170

(22) Filed: Apr. 24, 2026

(30) Foreign Application Priority Data
May 7, 2025 (DE) 10 2025 117 411.3

(51) Int. Cl. G01R 31/28; G01R 1/067; G01R 1/073

(52) U.S. Cl. CPC G01R 31/2891; G01R 1/06722; G01R 1/07342

(57) ABSTRACT

A support device for a test system for testing devices under test on wafer level, wherein the support device comprises a support structure configured for supporting a wafer comprising devices under test. A force contact is arranged at the support structure and configured for applying a test current to the wafer when arranged on the support structure. A sense contact is arranged at a fixed position of the support structure, being electrically decoupled from the force contact, and being configured for sensing a sense voltage at the wafer in response to the applied test current.

### CROSS-REFERENCE TO RELATED APPLICATION

This Utility Patent Application claims priority to German Patent Application No. 10 2025 117 411.3 filed May 7, 2025, which is incorporated herein by reference.

### TECHNICAL FIELD

The present disclosure relates to a support device, a test system, and a method.

### BACKGROUND

After manufacturing semiconductor chips on a wafer, such semiconductor chips are usually tested concerning their function. For this purpose, a test system which may comprise a prober and an electric test unit may be provided in which such semiconductor chips are tested as devices under test (DUT) on wafer level.

However, parasitic phenomena acting on the test system may reduce accuracy or may even falsify electric signals applied and/or detected during testing the DUT on wafer level. This may deteriorate reliability of the test.

### SUMMARY

There may be a need for safely and reliably testing a device under test on wafer level.

According to an exemplary embodiment, a support device for a test system for testing devices under test on wafer level is provided, wherein the support device comprises a support structure configured for supporting a wafer comprising devices under test, a force contact arranged at the support structure and configured for applying a test current to the wafer when arranged on the support structure, and a sense contact arranged at a fixed position of the support structure, being electrically decoupled from the force contact, and being configured for sensing a sense voltage at the wafer in response to the applied test current.

According to another exemplary embodiment, a test system for testing devices under test on wafer level is provided, wherein the test system comprises a support device having the above-mentioned features, and an electric test unit coupled with the support device for supplying the test current and for analyzing the sense voltage.

According to still another exemplary embodiment, a method is provided which comprises arranging a wafer comprising devices under test on a support structure, applying a test current to the wafer by a force contact arranged at the support structure, and sensing a sense voltage at the wafer in response to the applied test current by a sense contact arranged at a fixed position of the support structure and being electrically decoupled from the force contact.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIG. 1 illustrates a cross sectional view of a test system with a support device according to an exemplary embodiment.

FIG. 2 illustrates a plan view of a back side of a support structure of a support device according to an exemplary embodiment.

FIG. 3 illustrates a plan view of a front side of the support structure of the support device according to FIG. 2.

FIG. 4 illustrates a measured voltage distribution of a wafer on a surface of a conventional support device without sense contact and a measured voltage distribution of a wafer on a surface of a support device according to an exemplary embodiment with sense contact.

FIG. 5 illustrates a cross sectional view of a test system with a support device according to an exemplary embodiment.

### DETAILED DESCRIPTION

The examples described herein provide a support device for a test system for testing devices under test (DUT), such as semiconductor chips, while the latter are still integrally connected on wafer level, in particular by still forming part of the wafer compound. A support structure of the support device may support such a wafer which may comprise the devices under test still forming an integral part of the wafer. A force contact at the support structure may be used to apply an electric test current to the wafer, in particular to the entire wafer or to a respective device under test of the wafer, while the wafer is mounted on the support structure. Advantageously, an additional sense contact may be provided which may be located at a fixed (for instance at a predefined unchangeable) position of the support structure. Said additional sense contact may be electrically decoupled from the force contact, for example by being electrically insulated from the force contact. Furthermore, the sense contact may be adapted to sense an electric sense voltage at the wafer, for instance at a specific device under test. Such a sense voltage may be generated at the sense contact in response to the test current applied by the force contact. Such a configuration may have advantages: Firstly, the electrically separated provision of a force contact for test current supply and a fixed positioned sense contact for sense voltage detection may also allow to contact and to test devices under test on the wafer without the need to provide a back side metallization to the wafer already during testing. Thus, the test may be executed prior to additional processes such as back side metallization and/or semiconductor substrate thinning, which may simplify and increase the flexibility of the test. Secondly, the provision of two mutually isolated force and sense contacts may allow to use regulation capabilities of the test system to compensate a voltage drop on a wafer back side interface, in particular in the absence of a back side metallization of the wafer. Thirdly, by configuring the sense contact to be spatially fixed at the support structure (for instance fixedly arranged with a voltage sense tip on the front side of a support plate carrying the wafer) may allow to arrange the sense contact at a position which is particularly appropriate for sensing a precise voltage. A fixed position may also enhance reproducibility and comparability of test results. Furthermore, such a fixed configuration may avoid effort in terms of moving the sense contact along the support structure, which may simplify the construction of the support device in the test system.

In the following, further exemplary embodiments of the support device, the test system, and the method will be explained.

In the context of the present application, the term “support structure” may particularly denote a physical body (such as a support plate, in particular an electrically conductive support plate) configured for supporting or carrying a wafer to be tested. Such a support structure may fulfil a mechanical support function and an electric coupling or testing function.

In the context of the present application, the term “test system” may particularly denote a system for testing devices under test and comprising a support device for carrying and electrically contacting one or more devices under test, and an electric test unit for providing an electric test functionality. The support device may be a mechanical carrier for mechanically supporting a wafer encompassing devices under test, and may also have an electronic function by providing force and sense contacts. The electric test unit, which may be functionally coupled with the support device, may provide electronic functionality to the test system, for instance by comprising a test current source and a voltage measurement device. An electric test of a device under test may involve the application of one or more electric stimulus signals to the devices under test, for instance to chips of a wafer. The test may also include the detection and processing of one or more electric response signals in response to the application of the stimulus signal(s).

In the context of the present application, the term “device under test” (DUT) may particularly denote an electronic component such as a semiconductor wafer or a semiconductor chip which shall be tested concerning its desired functionality after its manufacture or after manufacture of part thereof. In particular, the device under test may be an electronic member configured as a power semiconductor wafer or chip, for instance for automotive applications and/or for mobile communications applications.

In the context of the present application, the term “on wafer level” may particularly denote that the device under test being tested may be integrally connected in a wafer compound during testing.

In the context of the present application, the term “force contact” may particularly denote at least one electric contact for electrically contacting the wafer or one or more devices under test thereof for test current application. For example, the force contact may apply an electric current to the wafer or part thereof. For instance, the force contact may apply such a current to an entire main surface of the wafer by applying the current to an entire main surface of a metallic support plate of the support device. This may lead to a current flow between an entire main surface of the wafer and a specific position or region of the opposing main surface of the wafer, which may correspond to one or more specific devices under test.

In the context of the present application, the term “sense contact” may particularly denote at least one electric contact, preferably exactly one electric contact, for electrically contacting the wafer or a device under test thereof for voltage sensing purpose. The sense contact may comprise an electrically conductive contact tip in direct physical contact with a back side of the wafer when the latter rests on a support plate through which the sense contact may be guided towards the wafer. For example, the sense contact may sense an electric voltage at the wafer or part thereof when an electric test current has been applied by a force contact. For instance, the sense contact may sense the sense voltage between a specific position (in particular a fixed reference position) at a main surface of the wafer (in particular a back side of the wafer) and, in particular in cooperation with a sense needle, a specific position at the opposing main surface of the wafer (in particular a front side of the wafer), which may for example correspond to a specific device under test.

In an embodiment, the support structure comprises a metal plate, for example a circular metal plate. A support structure embodied as support plate, in particular as metal plate, may provide a simple construction for carrying the wafer and contacting the latter with a sense contact which can be guided through such a metal plate up to a back side of the wafer resting on the metal plate. It may also be possible to add such a metal plate to an existing chuck construction, in order to retrofit a test system with a spatially fixed and electrically insulated voltage sense contact.

In an embodiment, the metal plate has a through hole at which an electrically insulating structure is arranged, wherein the sense contact is guided through the electrically insulating structure and the through hole. For instance, the sense contact may be surrounded by a dielectric sleeve which can be inserted in the through hole. This may lead to a spatial fixation of the sense contact while simultaneously ensuring a reliable electric decoupling thereof with respect to the metal plate and with respect to the force contact. By taking this measure, a simple design may be combined with an electrically reliable guiding of the sense contact to the back side of the wafer resting on the metal plate. Furthermore, short electric paths may be achieved in this way, which may render losses small and signal integrity high.

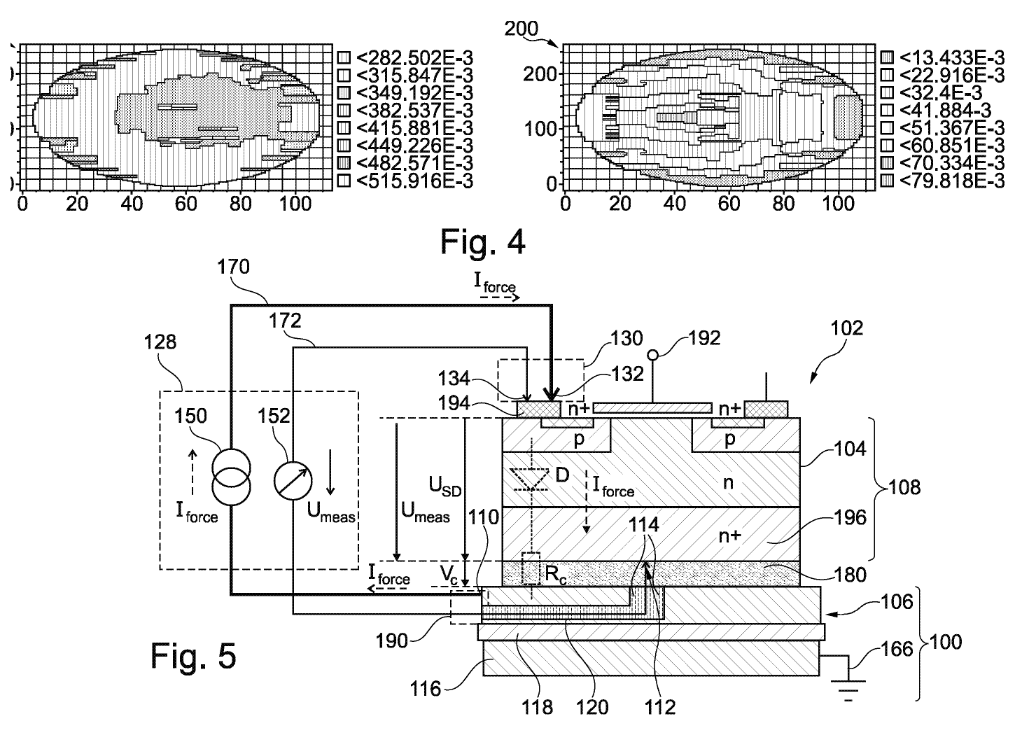

In an embodiment, the sense contact is arranged in a central region of the metal plate, for example at a center of the circular metal plate or radially spaced from a center of the circular metal plate by less than a half of a radius of the circular metal plate. For example, the sense contact may be arranged radially spaced from a center of the circular metal plate by not more than a quarter of a radius of the circular metal plate. For instance, the radial spacing of the sense contact position from the center of the circular metal plate may be between 20% and 40% of a radius of the circular metal plate. Referring to the measurement results of FIG. 4, arranging the sense contact at the center or close to the center may significantly reduce a measure voltage drop and may therefore strongly suppress any remaining measurement error. While arranging the sense contact at the center may be a preferred option, additional design constraints may need to be considered in specific embodiments. For instance in a scenario in which the test system and the support device comprise a suction mechanism for generating a vacuum suction force for holding the back side of the wafer on the front side of the support structure, vacuum channels may be formed on the back side of the support structure for connecting a vacuum via through holes extending through the support structure to its front side for exerting a vacuum suction force to the wafer. In such a scenario, an advantageous design rule for the position of the sense contact may be close to the center of the circular support plate and sufficiently remote from the vacuum channels and the vacuum through holes.

In an embodiment, the sense contact comprises a spring biased pin or a pogo pin. Using a spring biased sense contact, the sense contact may be pressed with a biasing force onto the wafer. Such a biasing force may be generated by a mechanical spring or as a magnetic biasing force. A sense contact biased with a biasing force against a surface of the wafer may allow an electrically conductive tip of the sense contact to penetrate through a semiconductor oxide film or layer which may be present on a non-metallized main surface of the wafer resting on the support structure. This may lead, in turn, to an efficient compensation of a voltage drop on the wafer back side.

In an embodiment, the sense contact is configured as ohmic contact. In the context of the present application, the term “ohmic contact” may particularly denote a contact providing a linear voltage/current characteristic. Such an ohmic contact may avoid the artificial generation of a rectifying metal-semiconductor-contact between sense contact and wafer with non-metallized back side. An ohmic contact may ensure a transition between a metal and a semiconductor with low electrical resistance, which behaves like an ohmic resistor and does not have a rectifying effect like a Schottky contact. Such a configuration may ensure a high accuracy of the test.

In an embodiment, the sense contact is configured for exerting a force of at least 1 Newton, for example of at least 2 Newton, on the wafer. For instance, such a force may be generated by a biasing element, such as a biasing spring, of the sense contact. This may ensure that the sense contact reliably penetrates through a semiconductor oxide film on the non-metallized back side of the wafer. As a result, the behavior of the sense contact as an ohmic contact may be promoted.

In an embodiment, the sense contact comprises tungsten, tungsten carbide or aluminum. Such a material may be sufficiently hard for withstanding biasing forces for pressing the sense contact onto the back side of the wafer. At the same time, such a material selection for the tip of the sense contact may avoid an undesired rectifying metal-semiconductor contact. By taking this measure, the behavior of the sense contact as an ohmic contact may be promoted.

In an embodiment, the sense contact has a tip radius in a range from 0.10 mm to 0.51 mm. A sufficiently large tip radius of at least 0.1 mm may lead to a sufficiently large contact area for keeping contact resistance moderate. At the same time, a sufficiently small tip radius of not more than 0.5 mm may simplify or ensure penetration of a semiconductor oxide film on a non-metallized back side of the wafer by the sense contact tip. As a result, the behavior of the sense contact as an ohmic contact may be promoted.

Preferably, the aforementioned design rules concerning minimum exerted force, material selection and tip radius of the sense contact may be combined for obtaining a sense contact behaving truly as an ohmic contact. This may lead to an excellent precision of the test.

In an embodiment, the support device comprises a chuck under the support structure. Such a chuck may provide mechanical support also for a support plate. The chuck may be electrically grounded.

In an embodiment, the support device comprises a ceramic plate between the chuck and the support structure. Such a ceramic plate may be electrically insulating for properly electrically decoupling the support structure (which may comprise a support plate) from a surrounding. The support structure may be made of an electrically conductive material such as a metal, in particular for applying a test current to an entire surface of a carrier via a force contact connected with such a metal plate. At the same time, a ceramic plate is mechanically stable and may also have a high thermal conductivity for preventing overheating during testing.

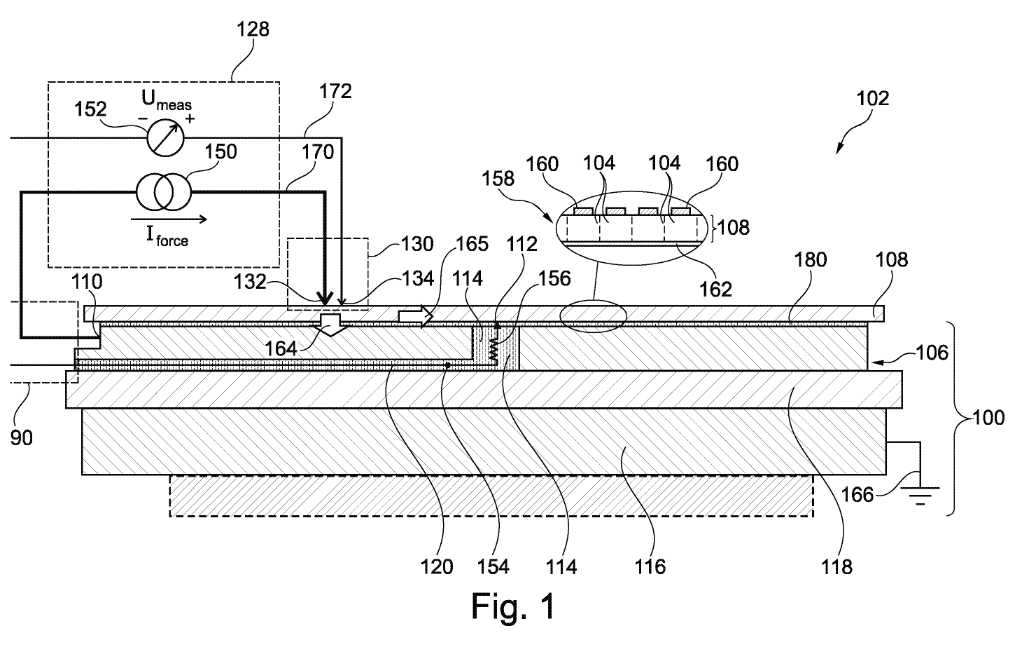

In an embodiment, the support device comprises an electric cable electrically coupled with the sense contact and extending between the support structure and the chuck, in particular between the support structure and the ceramic plate. For example, a first portion of such an electric cable may be guided horizontally along a bottom main surface of the support plate (for instance may be arranged in a groove or recess at the bottom main surface), whereas a connected second portion of the electric cable may be guided vertically through a through hole extending through the support plate. Such a design (see for instance FIG. 1) may lead to very short electric paths and therefore low losses.

In another embodiment, the support device comprises an electric cable electrically coupled with the sense contact and extending through the chuck and/or through the ceramic plate to the support structure. As an alternative to the previously described embodiment, the electric cable for guiding the sense contact to the back side of the wafer resting on the support structure may also be guided through at least one through hole in chuck and/or in ceramic plate and through a through hole in the support plate. This may increase the freedom of design.

In an embodiment, the test system comprises the wafer arranged with its back side on the support structure, wherein said back side is free of a metallization. For example, said back side of the wafer may comprise at its exterior surface a semiconductor surface with an oxide layer thereon. Such a semiconductor oxide layer may be generated naturally in the absence of a back side metallization. It may however disturb sense voltage measurement. Advantageously, it may be penetrated partially or entirely by a correspondingly designed sense contact (in particular adjusted correspondingly in terms of material selection, tip radius design and/or contact pressure). Advantageously, devices under test of such a wafer may be tested on wafer level without back side metallization and without back side etching prior to testing due to the fixed and isolated voltage sense contact of exemplary embodiments, in particular when configured as ohmic contact. Hence, further processing of the wafer (for instance back side thinning, back side metallization, singulation) may be done after testing wafer level. This may increase the freedom of design and the effort of the test.

In an embodiment, the test system comprises a probe card having needles for electrically contacting a device under test at a front side of the wafer opposing a back side of the wafer with which the wafer is arranged on the support structure. In particular, the needles may comprise a force needle for contributing to applying the test current to the electrically contacted device under test and a sense needle for contributing to sensing the sense voltage at the electrically contacted device under test. For instance, such a probe card may comprise a force needle and a sense needle being electrically insulated with respect to each other. The force needle may cooperate with the force contact for applying a test current. The sense needle may cooperate with the sense contact for sensing a response voltage. It is possible to provide one or a plurality of force needles and/or sense needles.

For example, it may be advantageous to apply the test current by arranging the back side of the wafer directly on a metallic support plate which is electrically coupled (in particular laterally) with the force contact. At the front side of the wafer, the force needle may contact with its tip a specific portion of the wafer. When a test current source applies a test current between force contact and force needle, the test current will be applied to the wafer. Simultaneously, it may be advantageous to sense an electric voltage by contacting a specific position of the back side of the wafer with the electrically conductive tip of the sense contact. At the front side of the wafer, the sense needle may contact with its tip a specific portion of the wafer. When a voltage measurement device is electrically connected between sense contact and sense needle, a sense voltage in response to the applied test current will be measured between the two opposing main surfaces of the wafer.

In an embodiment, the probe card is configured for scanning the front side of the wafer for subsequently testing different devices under test of the wafer. For instance, one or a group of devices under test may be tested at a time. Thereafter, the probe card may move to the next one or to the next group of devices under test for testing. While the at least one sense needle and the at least one force needle of the probe card may be movable relative to the wafer, the force contact and the sense contact may remain permanently spatially fixed.

In an embodiment, the method comprises arranging a non-metallized back side of the wafer on the support structure. For example, the method may comprise guiding the sense contact to penetrate through an oxide layer up to a semiconductor surface on the back side of the wafer. By testing devices under test on wafer level directly on a wafer with non-metallized back side, without the need of special wafer treatment, the testing effort may be kept small. A natural semiconductor oxide film generated on the non-metallized back side of the wafer may be penetrated partially or entirely by the sense contact for enhancing accuracy of the voltage detection.

In an embodiment, the method comprises testing chips as the devices under test. In particular, the method may comprise testing power semiconductor chips as the devices under test. For example, the method comprises testing semiconductor chips having a vertical current flow between two opposing main surfaces as the devices under test. For instance, power semiconductor chips may be tested. It may be possible to test field effect transistor chips with vertical current flow. In an embodiment, the method comprises testing integrally connected dies or chips of a wafer as the devices under test, in particular a wafer having a diameter of at least 200 mm, more particularly at least 300 mm.

In an embodiment, the devices under test may be embodied as transistor chips each having a source terminal, a drain terminal and a gate terminal. In particular, the source terminal and the gate terminal may be formed on the same main surface of the electronic chip. The drain terminal may be formed on an opposing other main surface of the electronic chip. Such a transistor chip may be a chip fulfilling the function of a transistor, in particular of a field effect transistor. Such a transistor chip may be used for instance for semiconductor power applications.

In an embodiment, each device under test, embodied as semiconductor chip, comprises at least one of the group consisting of a controller circuit, a driver circuit, and a power semiconductor circuit. All these circuits may be integrated into one semiconductor chip, or separately in different chips. For instance, a corresponding power semiconductor application may be realized by the chip(s), wherein integrated circuit elements of such a power semiconductor chip may comprise at least one transistor (in particular a MOSFET, metal oxide semiconductor field effect transistor), at least one diode, etc. In particular, circuits fulfilling a half-bridge function, a full-bridge function, etc., may be manufactured and tested.

As substrate or wafer for the semiconductor chips, a semiconductor substrate, preferably a silicon substrate, may be used. Alternatively, a silicon oxide or another insulator substrate may be provided. It is also possible to implement a germanium substrate or a III-V-semiconductor material. For instance, exemplary embodiments may be implemented in GaN or SiC technology.

Before exemplary embodiments will be described in more detail referring to the figures, some general considerations will be summarized based on which exemplary embodiments have been developed.

In conventional test systems, measurement problems have been observed on wafer level for MOS-FET power switches in vertical technology. Such devices are characterized by a vertical current flow from wafer top side to wafer back side and may use the wafer back side as electrical supply pin during wafer test. Different from the electrical metal contacts (such as pads) on the wafer top side, the wafer back side may not have dedicated contact pads and may not have back side metallization for wafer test. The back side of a wafer may be formed by n+ or p+ doped silicon with an intrinsic semiconductor oxide layer on top. An electrical contact may be provided by a prober chuck (which may comprise a metal plate), which may hold the wafer during wafer test, i.e. during testing devices under test on wafer level. The contact resistance on the wafer back side may be determined by the surface characteristics of the silicon wafer back side and by the surface characteristics of the prober chuck.

However, a measurement problem may occur in conventional test systems. In particular, it may happen that the contact resistance on wafer back side shows random variations (for example from lot to lot, from wafer to wafer, from test cell to test cell, etc.). This may lead to unstable wafer test results. Even on the same test cell, contact resistance variations can be observed at re-test, after unloading and loading the same wafer again into the prober, etc.

Such issues may conventionally lead to the risk of a yield-loss at wafer test and at die level screening (DLS) due to unstable test results (such as skewed distributions). Thus, a quality-risk may occur due to unstable test conditions (for example applied stress-voltage is too low) during stress tests. One conventional approach of addressing such issues is the introduction of a special wafer back side etch process (which may be denoted as rough etching) prior to production test for the affected products. However, such an additional process may be cumbersome and may increase the testing effort and time.

By a wafer back side etching process, it may be possible to remove semiconductor oxide layers and increase roughness of wafer back side for better mechanical and/or electrical contact between wafer back side and prober metal plate. Investigations on corresponding products show a significant reduction of the back side contact resistance and a better reproducibility of the wafer test results. Thus, such a wafer back side etch process is conventionally implemented at various wafer manufacturing locations. However, wafer back side etching prior to testing may increase the manufacturing and testing effort, due to the execution of an additional wafer process step, which is needed for improving the wafer test stability only. Furthermore, it may be difficult to define quality criteria for the wafer back side etching. Beyond this, there may be a risk of re-occurrence of contact problems during wafer test in case of etching process variations. Moreover, the total wafer back side current may increase with the number of devices that are tested in parallel during one touch-down of the wafer prober (parallel test factor). Under certain circumstances, the achieved reduction of the wafer back side contact resistance may be insufficient for certain tester platforms with high parallel test factor at wafer test.

Furthermore, a prober chuck construction can be considered in which the wafer back side is contacted by a metal plate (which may be denoted as “add-on plate”). Force- and sense-contacts of the tester instruments may be shorted together on the add-on plate. With this construction, the voltage drop on the wafer back side interface (due to its contact resistance) cannot be compensated and may lead to wrong measurement results.

Exemplary embodiments may overcome one or more of the above mentioned and/or other conventional shortcomings concerning testing devices under test on wafer level.

According to an exemplary embodiment, a support device for a test system for testing devices under test (DUT) on wafer level may be equipped with a sense contact being arranged at a fixed reference position (which may be unchangeable) and being electrically decoupled from a force contact. More specifically, a support structure of such a support device may carry a wafer including integrally connected devices under test. The back side force contact may be operated to provide, in particular in collaboration with a front side force needle, a test current to the wafer or part thereof. The spatially fixed back side sense contact may be operated to sense, in particular in collaboration with a front side sense needle, a sense voltage at the wafer or part thereof in response to the applied test current. Advantageously, force and sense contact may be electrically decoupled from each other or may be galvanically separated so as to avoid electric artefacts. Such a configuration may allow to test devices under test on wafer level, wherein the wafer may be naked on its back side, i.e. non-metallized. Back side treatment of the wafer, for instance a back side etch, prior to testing, may be dispensable. The provision of electrically separated force and sense contacts may allow compensating, partially or entirely, a voltage drop on the wafer back side interface. Beyond this, a sense contact at a fixed position of a support structure avoids moving parts and allows to arrange the sense contact where its accuracy is appropriate.

Hence, exemplary embodiments may sense a voltage on a wafer back side. More specifically, exemplary embodiments may avoid a wafer back side etching process in the context of a DUT test on wafer level. This may be achieved by a simple adaptation of the wafer test cell. In particular, this may be accomplished by introducing a voltage sense contact on a support device on a prober chuck and using the regulation capabilities of the tester instruments to compensate the voltage drop on the wafer back side interface (in particular by implementing a voltage feedback loop).

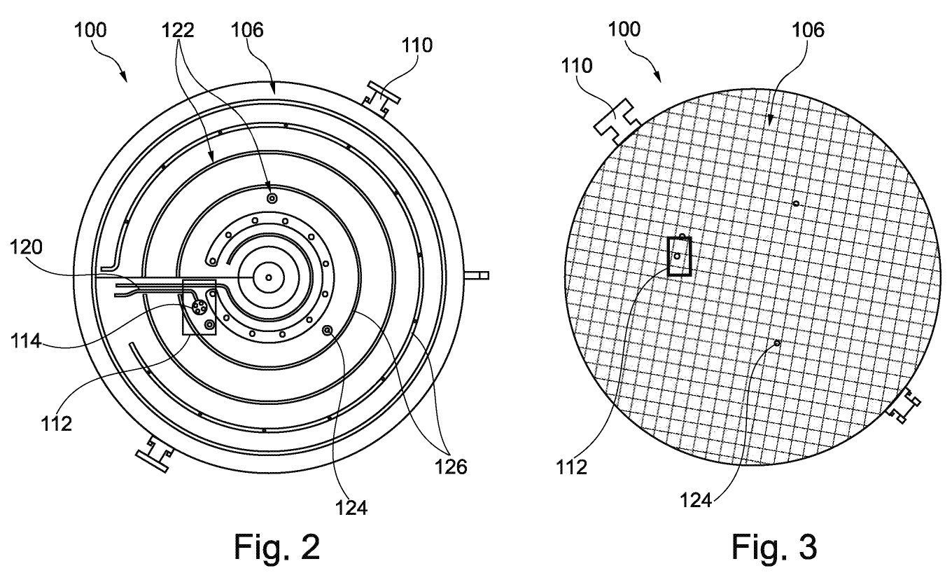

Such an embodiment has advantages: Firstly, it may be possible to avoid the additional testing and manufacturing effort per wafer by a one-time modification of the wafer test cell. The implementation of a voltage sense contact on the wafer back side can be achieved with a minor modification of the metal plate on the prober chuck (see FIG. 2 and FIG. 3).

In embodiments, care should be taken that preferably, when compensating the voltage drop on the wafer back side, a linear voltage/current characteristic of the sense contact is achieved, i.e. that the sense contact preferably behaves as an ohmic contact. Such an ohmic contact between the silicon surface and the voltage sense probe may be advantageously achieved by a proper selection of the sense probe material. This may avoid the undesired creation of a rectifying metal-semiconductor contact, which may form a parasitic Schottky diode.

Moreover, it may be advantageous that an intrinsic semiconductor oxide layer on the wafer back side can be penetrated by the voltage sense probe or sense contact. Therefore, a certain probe tip radius and a minimum contact force of the sense probe may be preferred. On the other hand, a too high contact force might disturb the wafer loading process to the chuck, which may rely on a vacuum suction system (this may be denoted as “Bernoulli wafer handling”).

Rather than providing a conventional combined force/sense-contact on the wafer back side, exemplary embodiments may advantageously provide mutually electrically isolated force-/sense-contacts. The force contact may be used to carry high current (for instance at least 1 Ampère or at least 10 Ampère) and may be provided by the metal plate of the prober chuck. Due to the high current during wafer test, a voltage drop may occur on the wafer back side interface. Advantageously, a sense contact may be added to the prober chuck construction. This sense contact may be configured to sense the electric voltage of the wafer back side. Said sense contact may be configured or operated so that it does not carry high electric current, because it may be connected to a high impedance voltage sense input of the test system (for instance for establishing a voltage feedback loop).

For instance, the tip size, contact force and/or material of the voltage sense contact can be properly chosen for contacting silicon surfaces. Advantageously, the sense contact may exert a contact force of at least 1 Newton to the wafer. Beneficially, this may allow to penetrate an intrinsic semiconductor oxide layer on the wafer surface. Moreover, for contacting doped silicon wafers, the probe tip radius may be at least 2 mil, preferably in the range from 4 mil to 20 mil. Without wishing to be bound to a specific theory, it is presently believed that too small probe tips do not match perfectly with semiconductor (in particular silicon) surfaces, because the small contact area leads to an increased contact resistance in this case. A preferred contact material of the sense contact for contacting semiconductor (in particular silicon) surfaces is tungsten carbide. The hardness of this probe tip material may help to penetrate semiconductor oxide layers and its rough surface may reduce the contact resistance. Additionally, the work function of tungsten carbide may be close to the work function of semiconductors such as silicon, so that Schottky barriers can be avoided and an ohmic contact with linear voltage/current characteristic can be established.

Exemplary embodiments may improve the stability and yield of wafer test, for instance of a wafer comprising vertical MOS-FET devices. This may be achieved by equipping a wafer test system (in particular a wafer prober thereof) with a voltage sense contact for the wafer back side. Preferably, a two-wire contact principle may be used for this purpose.

In particular, a naked wafer back side without metallization thereon may be contacted by a sense contact. This man allow to measure precisely which electric voltage is experienced by the respective chip. Descriptively speaking, this man allow to precisely measure a body diode. Mutually isolated force and sense contact, at least the latter being spatially fixed, may collaborate for ensuring a simple and reliable test.

FIG. 1 illustrates a cross sectional view of a test system 102 with a support device 100 according to an exemplary embodiment. FIG. 2 illustrates a plan view of a back side of a support structure 106 of the support device 100 according to an exemplary embodiment. FIG. 3 illustrates a plan view of a front side of the support structure 106 of the support device 100 according to FIG. 2.

The test system 102 according to FIG. 1 may be configured for testing devices under test 104 on wafer level. More specifically, the test of the semiconductor chip-type devices under test 104 can be executed while they are still integrally connected on a wafer 108. This can be seen in a detail 158 of a portion of the wafer 108 showing integrally connected devices under test 104 arranged side-by-side. In fact, the wafer 108 may comprise a matrix-like arrangement of semiconductor chip-type devices under test 104 arranged in rows and columns. The wafer 108 may be a circular disc. For instance, the devices under test 104 may be transistor chips, such as metal oxide semiconductor field effect transistor chips. The devices under test 104 may experience a vertical current flow during operation. As shown in detail 158, the front side of the wafer 108 with its devices under test 104 may comprise a front side metallization 160, for instance comprising metallic pads. In contrast to this, the back side of the wafer 108 with its devices under test 104 may be free of a back side metallization. However, a semiconductor oxide film 162 may be present on the back side of the wafer 108. Apart from the semiconductor oxide film 162, the wafer back side may be for example n+ or p+ doped silicon without metallization. When the devices under test 104 of the wafer 108 are field effect transistor chips, it is for instance possible that the source terminals and the gate terminals of the field effect transistor chips are provided on the upper main surface of the wafer 108, whereas the drain terminals of said field effect transistor chips are provided on the lower main surface of the wafer 108.

Advantageously, the devices under test 104 can be tested on wafer level. More specifically, the devices under test 104 can be tested although their back side (i.e. the lower main surface according to FIG. 1) is not yet metallized. For example, the exposed back side of wafer 108 may consist of semiconductor or semiconductor oxide material during testing. This may make it possible that additional processes such as back side wafer thinning and formation of wafer back side metallization can be carried out after testing.

Referring again to the test system 102 of FIG. 1, said test system 102 comprises a bottom-sided support device 100 providing mechanical support for the wafer 108 to be tested and contributing to the electric functionality of the test system 102. Furthermore, test system 102 comprises an electric test unit 128 which is electrically coupled with the support device 100 for supplying a test current and for analyzing a sense voltage, as described below in further detail. A current source 150 and a voltage measuring device 152 may form part of electric test unit 128.

Still referring to FIG. 1, the illustrated support device 100 has a support structure 106 configured for supporting wafer 108 comprising devices under test 104. For example, the support structure 106 may comprise an electrically conductive support plates, such as a metal plate (for instance comprising copper and/or aluminum), on which the wafer 108 is mounted.

Moreover, a single force contact 110 is arranged at the support structure 106 and is configured for applying an electric test current to the wafer 108 when arranged on the support structure 106. Force contact 110 may be a back side force contact. This force contact 110 may be connected (for example laterally connected) to the metal plate for supplying the test current to the metal plate and from there to the back side of the wafer 108 as a whole. Hence, the force contact 110 may be configured as a current supply pin for the entire back side area of the wafer 108. Moreover, current source 150 is provided which is connected to the force contact 110 for supplying the electric test current. Said test current is denoted as I_{force} in FIG. 1. One of the terminals of the current source 150 is electrically coupled with the force contact 110. The other terminal of the current source 150 is electrically coupled with a test current needle or force needle 132 of a probe card 130 of the test system 102. The force needle 132 has a metallic tip which is configured for electrically contacting a device under test 104 at a front side of the wafer 108 opposing a back side of the wafer 108 with which the wafer 108 is arranged on the support structure 106 and which is electrically coupled with the force contact 110.

Advantageously, the support device 100 further comprises a single sense contact 112 which is configured for sensing a sense voltage at the wafer 108 in response to the test current applied by the force contact 110 in cooperation with current source 150 and force needle 132. In the shown embodiment, the sense contact 112 is arranged or located at an unchangeably fixed reference position of the support structure 106. Thus, the sense contact 112 is fixed in place with respect to the support structure 106 by being fixedly mounted at the support plate. More specifically, the sense contact 112 is electrically decoupled from the force contact 110. Thus, the sense contact 112 is electrically and mechanically separated from the force contact 110. Additionally, the sense contact 112 is also electrically decoupled from the metal plate of the support structure 106. The electrical isolation of the sense contact 112 is indicated schematically by reference sign 154 in FIG. 1. For realizing this electrical isolation, a through hole may be formed in the metal plate constituting the support structure 106, and the sense contact 112 may be guided through said through hole so as to directly contact with its electrically conductive tip a back side or bottom main surface of the wafer 108. To ensure the electrical decoupling between the sense contact 112, on the one hand, and the force contact 110 and the metal plate constituting the support structure 106 on the other hand, an electrically insulating structure 114, for instance an electrically insulating sleeve, may surround the sense contact 112 in the through hole. Preferably, such an electrically insulating sleeve may be plugged into the through hole of the metal plate. This may fix the sense contact 112 in place and may reliably ensure its electrical isolation with respect to metal plate and force contact 110.

A voltage measuring device 152 is provided and connected between the sense contact 112 and a voltage detection needle or sense needle 134 of the probe card 130 for measuring a test voltage Uₘₑₐₛ generated when the electric test current I_{force} is applied. One of the terminals of the voltage measuring device 152 is electrically coupled with the sense contact 112. The other terminal of the voltage measuring device 152 is electrically coupled with the voltage detection or sense needle 134 of the probe card 130 of the test system 102. The sense needle 134 is configured for electrically contacting the device under test 104 at the front side of the wafer 108 opposing the back side of the wafer 108 with which the wafer 108 is arranged on the support structure 106 and which is directly connected with the tip of the sense contact 112.

Descriptively speaking, the illustrated exemplary embodiment may provide a support structure 106 configured as add-on plate with separated force contact 110 and sense contact 112. A Kelvin contact may be provided on the wafer back side for compensating the voltage drop on the wafer back side interface. A voltage drop may be compensated by the back side sense contact 112.

The needles 132, 134 of the probe card 130 may comprise the already mentioned force needle 132 for contributing to applying the test current to the electrically contacted device under test 104 and the already mentioned sense needle 134 for contributing to sensing the sense voltage at the electrically contacted device under test 104. The needles 132, 134 may be electrically separated from each other. Force needle 132 belongs to a force line 170 for current forcing. Sense needle 134 belongs to a sense line 172 for voltage sensing. The force line 170 and the sense line 172 may be separate from each other for providing separated or electrically decoupled force contact 110 and sense contact 112.

In order to promote an ohmic contact like behavior, the sense contact 112 may be configured for exerting a biasing force of at least 1 Newton onto the back side of the wafer 108. This can be achieved by configuring the sense contact 112 so that the latter exerts a spring-generated biasing force onto the wafer 108. For this purpose, the sense contact 112 may be equipped with a spring biased pin, as shown in FIG. 1. The biasing spring is indicated by reference sign 156. It is also possible that the sense contact 102 is configured as a pogo pin. By taking this measure, a sufficiently large contacting force between sense contact 112 and wafer 108 can be ensured. This may make it possible that the spring 156 presses the tip of the sense contact 112 onto the back side of the wafer 108 to penetrate through a semiconductor oxide film 162 on the back side of the wafer 108. This avoids the measurement of a parasitic voltage drop as an artifact of the semiconductor oxide film 162.

In order to further promote an ohmic contact like behavior, the sense contact 112 may be made of tungsten, tungsten carbide or aluminum. For a silicon surface of wafer 108, tungsten or tungsten carbide may be the most preferred material. The mentioned materials may have a sufficiently large hardness to be able to penetrate through semiconductor oxide film 162 on the back side of the wafer 108.

In order to further promote an ohmic contact like behavior, the sense contact 112 may have a contact tip for contacting wafer 108 with a tip radius in a range from 0.1 mm to 0.5 mm. These tip radii may be large enough for ensuring that a contact area with the wafer 108 is large enough to avoid an excessively large contact resistance.

Preferably, the sense contact 112 is configured as ohmic contact so that a Schottky barrier may be avoided. Advantageously, this may lead to a linear voltage/current characteristic. One, some or all of the measures described herein for ensuring that the sense contact 112 is an ohmic contact may be taken.

As already mentioned, the support structure 106 comprises a metal plate, which is in the present embodiment a circular metal plate. Descriptively speaking, the support structure 106 may be an add-on plate with cable trench. For example, the metal plate may be of copper or aluminum. The metal plate is shown in FIG. 2 from the bottom side and in FIG. 3 from the top side facing the wafer 108 during operation. As can be taken from each of FIG. 1 to FIG. 3, the metal plate has a vertical through hole at which the sleeve-type electrically insulating structure 114 is arranged. The sense contact 112 is guided through a central through hole of the sleeve-type electrically insulating structure 114 and thereby through the through hole of the metal plate. Advantageously, the sense contact 112 can be arranged in a central region of the metal plate. For example, the sense contact 112 may be arranged at or substantially at a center of the circular metal plate (not shown). In the illustrated embodiment, the sense contact 112 is radially spaced from a center of the circular metal plate by less than a half of a radius of the circular metal plate. For instance, the radial spacing of the sense contact 112 from the center of the circular metal plate may be between 20% and 40% of a radius of the circular metal plate. As will be demonstrated below referring to FIG. 4, this may have a positive impact on the accuracy of the voltage detection.

Now referring to FIG. 2, the support device 100 and the test system 102 may be provided with a vacuum suction mechanism 122 for sucking the wafer 108 onto the support structure 106 by a vacuum force. This may ensure that the wafer 108 remains at a well-defined position on the support structure 106. This ensures good alignment during testing. For example, the suction mechanism 122 may comprise suction through holes 124 extending through the support structure 106 for transferring a vacuum suction force from back side to front side of the metal plate. Additionally, the suction mechanism 122 may comprise suction channels 126 on the back side of the support structure 106 opposing the front side of the support structure 106 on which the wafer 108 is arranged. A vacuum force generated on the back side of the metal plate may be transferred via the suction channels 126 and the suction through holes 124 to the front side of the metal plate for pulling the wafer onto the metal plate. These sucking structures 124, 126 may impose constraints to the position of the sense contact 112. As shown in FIG. 2, the sense contact-related through hole extending through the metal plate-type support structure 106 may be arranged between sucking structures 124, 126. With the above-mentioned 20% to 40% rule, a good voltage accuracy and compatibility with the suction mechanism 122 may be achieved simultaneously.

Referring again to FIG. 1, the support device 100 further comprises a chuck 116 under the support structure 106. For example, chuck 116 may be electrically grounded, as shown by reference sign 166. The chuck 116 provides strong mechanical support. Furthermore, an electrically insulating and thermally conductive ceramic plate 118 can be arranged between the chuck 116 and the support structure 106. For instance, the ceramic plate 118 may be made of aluminum nitride. As shown in FIG. 1, an electric cable 120 is electrically coupled with the sense contact 112 and the voltage measuring device 152. Advantageously, the electric cable 120 extends between the support structure 106 and the ceramic plate 118 on the chuck 116 and is then guided through the through hole in the metal plate up to the upper main surface of the metal plate for contacting the wafer back side. This is a preferred arrangement of the electric cable 120, since it may ensure very short electric connection paths, and therefore low losses. However, in alternative embodiments, it may also be possible to guide the electric cable 120 through the chuck 116 and/or through the ceramic plate 118 (not shown). Reference sign 190 indicates a chuck cable with separated force and sense contacts 110, 112.

The probe card 130 may be configured for scanning along the front side of the wafer 108 for subsequently or sequentially testing different devices under test 104 of the wafer 108 one after the other. For instance, one device under test 104 or a group of devices under tests 104 may be tested at a time. After this test, the probe card 130 may be moved along the front side of the wafer 108 up to the next device(s) under test 104 to be tested. It is possible that one or multiple devices under test 104 are tested in parallel.

For executing the test, the wafer 108 with its integrally connected devices under test 104 may be arranged on the support structure 106. The devices under test 104 being still on wafer level may be semiconductor chips having a vertical current flow between two opposing main surfaces thereof. More specifically, the non-metallized back side of the wafer 108 can be arranged directly on the support structure 106. The tip of the sense contact 112 may be pressed onto the back side of the wafer 108 to penetrate through semiconductor oxide layer 162 up to a semiconductor surface on the back side of the wafer 108. The force contact 110 may be electrically coupled with the wafer 108 via the metal plate. Thereafter, a test current may be applied to the wafer 108 by the force contact 110 being arranged at the support structure 106. Moreover, the test method may comprise sensing a sense voltage at the wafer 108 in response to the applied test current by the sense contact 112 which is arranged at a fixed position of the support structure 106 and which is electrically decoupled from the force contact 110. Thanks to the sense contact 112 with the described configuration, the devices under test 104 may be tested on wafer level without having a back side metallization on the wafer 108 during the test.

When the test is completed, the wafer 108 may be subjected to further processing. For example the tested wafer 108 may proceed to thinning a back side of the wafer 108 after the testing. After that, the further processing treatment of the wafer 108 may comprise metallizing a back side of the wafer 108 post testing. After that, the wafer 108 may be separated into individual chips, for instance by dicing.

The prober-chuck construction according to FIG. 1 comprises the support structure 106 embodied as add-on plate, which is holding the wafer 108, and is equipped with additional voltage sense contact 112. For example, this sense contact 112 can be implemented as pogo- or spring-contact and is preferably electrically isolated from the rest of the add-on plate, which acts in conjunction with force contact 110. A preferred position of the sense contact 112 is close to the center of the add-on plate, to reduce or even minimize voltage-sense errors, due to lateral currents through the wafer 108.

With the construction according to FIG. 1 to FIG. 3, the main voltage drop on wafer back side interface 180 (which may have a contact resistance) can be compensated with a regulation loop of the test system 102. This two-wire contact principle may be denoted as Kelvin-contact and can be applied particularly advantageously to the wafer back side.

The construction of FIG. 1 is very simple. In principle, the add-on plate of the wafer prober can be configured in the shown way. This add-on plate or support structure 106 can be embodied as a removable part. Hence, the one-time effort of the test cell adaptation may be low. Moreover, the sense contact 112 can be easily accessed for maintenance and repair. Thus, it may be sufficient to equip an add-on plate with a pogo-contact and cable trench for voltage sensing. Due to constraints of the Bernoulli vacuum suction mechanism 122, the sense contact 112 may be placed slightly displaced with respect to the center of the add-on plate.

In FIG. 1, reference sign 164 may indicate a main back side voltage drop, which may be mostly compensated by the back side sense contact 112. Reference sign 165 may denote a potentially uncompensated voltage drop, due to electric current in the wafer 108, i.e. a measurement error. With the described design, said measurement error may be kept very small.

FIG. 4 illustrates a diagram 201 showing a measured voltage distribution of a wafer on a surface of a support plate of a conventional support device without sense contact. Moreover, FIG. 4 illustrates a diagram 200 showing a measured voltage distribution of a wafer 108 on a surface of a support plate 106 of a support device 100 according to an exemplary embodiment with sense contact 112. In a nutshell, FIG. 4 shows that an arrangement of the sense contact 112 at the center or close to the center of the support plate 106 and consequently of the wafer 108 is advantageous in terms of voltage accuracy. As can be taken from the shown scales, diagram 200 indicates an improvement over diagram 201.

FIG. 4 shows with diagram 200 the result of an evaluation of a support device of an exemplary embodiment. A wafer without special back side treatment (in particular without back side etching) was used for the evaluation of the prober chuck. The wafer back side surface comprises a highly n-doped silicon substrate with an intrinsic oxide layer in this case. The exemplary wafer contains high side power MOS-FETS with a vertical current flow from wafer top side to wafer back side. At each touch-down of the wafer prober, a set of 15 MOS-FETS are tested in parallel, with 200 mA test current per MOS-FET. This gives a total current through the wafer back side of 15 x 200mA = 3A per touch-down. The according voltage drop on the wafer back side interface has been measured per touch-down.

FIG. 4 shows with diagram 200 the according measurement results (as wafer maps) of a measurement run using a prober chuck with sense contact 112. It can be seen from the wafer map that the measured voltage drop on the wafer back side (i.e. the measurement error) is very small, and smaller than in diagram 201, due to the voltage sense contact 112. The illustrated wafer map run of diagram 200 also shows that there may be a small remaining measurement error, due to a lateral current flow in the wafer 108. This error increases with the horizontal distance between the device under test 104 and the voltage sense contact 112. The error may be lowest close to the center. Therefore, the best position for the voltage sense contact 112 may be close to the center of the add-on plate.

FIG. 5 illustrates a cross sectional view of a test system 102 with a support device 100 according to an exemplary embodiment.

In FIG. 5, the device under test 104 is a field effect transistor chip. A gate terminal is denoted with reference sign 192, a source terminal is denoted with reference sign 194 and a drain terminal is denoted with reference sign 196. D indicates a source drain diode to be measured. R_{C} denotes a contact resistance on the wafer back side. V_{C} denotes a contact resistance related voltage drop. I_{force} denotes the test current.

FIG. 5 relates to a U_{SD} voltage measurement, using the illustrated test system 102. The voltage-drop V_{C} on the wafer back side interface is by-passed by the voltage sense contact 112. The measured voltage is correct (Uₘₑₐₛ = U_{SD}).

Many alternatives to the exemplary embodiments presented are possible. For example, it may be possible to provide a plurality of sense contacts 112. More specifically, it may be possible to provide at least one further sense contact 112 arranged at at least one further fixed position of the support structure 106, being electrically decoupled from the force contact 110, and being configured for sensing at least one further sense voltage at the wafer 108 in response to the applied test current. Although the provision of only one sense contact 112 may be preferred due to its simplicity, multiple sense contacts 112 may be possible in other embodiments. By providing a plurality of sense contacts 112, a remaining small measurement error may be further reduced. The error may be the smaller, the smaller the distance of the respective sense contact 112 is with respect to the device under test 104.

Although specific examples have been illustrated and described herein, it will be appreciated by those of ordinary skill in the art that a variety of alternate and/or equivalent implementations may be substituted for the specific examples shown and described without departing from the scope of the present invention. This application is intended to cover any adaptations or variations of the specific examples discussed herein. Therefore, it is intended that this invention be limited only by the claims and the equivalents thereof.

It should be noted that the methods and devices including its preferred embodiments as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the invention and are included within its spirit and scope. Furthermore, all examples and embodiments outlined in the present document are principally intended expressly to be only for explanatory purposes to help the reader in understanding the principles of the proposed methods and systems. Furthermore, all statements herein providing principles, aspects, and embodiments of the invention, as well as specific examples thereof, are intended to encompass equivalents thereof.

1. A support device for a test system for testing devices under test on wafer level, wherein the support device comprises:
a support structure configured for supporting a wafer comprising devices under test;
a force contact arranged at the support structure and configured for applying a test current to the wafer when arranged on the support structure; and
a sense contact arranged at a fixed position of the support structure, being electrically decoupled from the force contact, and being configured for sensing a sense voltage at the wafer in response to the applied test current.

2. The support device according to claim 1, wherein the support structure comprises a metal plate, for example a circular metal plate.

3. The support device according to claim 2, wherein the metal plate has a through hole at which an electrically insulating structure is arranged, wherein the sense contact is guided through the electrically insulating structure and the through hole.

4. The support device according to claim 2, wherein the sense contact is arranged in a central region of the metal plate, for example at a center of the circular metal plate or radially spaced from a center of the circular metal plate by less than a half of a radius of the circular metal plate.

5. The support device according to claim 1, wherein the sense contact comprises a spring biased pin or a pogo pin.

6. The support device according to claim 1, wherein the sense contact is configured as ohmic contact.

7. The support device according to claim 1, wherein the sense contact is configured for exerting a force of at least 1 Newton on the wafer.

8. The support device according to claim 1, wherein the sense contact comprises tungsten, tungsten carbide or aluminum.

9. The support device according to claim 1, wherein the sense contact has a tip radius in a range from 0.10 mm to 0.51 mm.

10. The support device according to claim 1, comprising a chuck under the support structure.

11. The support device according to claim 10, comprising a ceramic plate between the chuck and the support structure.

12. The support device according to claim 10, comprising an electric cable electrically coupled with the sense contact and extending between the support structure and the chuck, in particular between the support structure and the ceramic plate.

13. The support device according to claim 10, comprising an electric cable electrically coupled with the sense contact and extending through the chuck and/or through the ceramic plate to the support structure.

14. A test system for testing devices under test on wafer level, wherein the test system comprises:
a support device according to claim 1; and
an electric test unit coupled with the support device for supplying the test current and for analyzing the sense voltage.

15. The test system according to claim 14, comprising the wafer arranged with its back side on the support structure, wherein said back side is free of a metallization, wherein for example said back side of the wafer comprises at its exterior surface a semiconductor surface with an oxide layer thereon.

16. The test system according to claim 14, comprising a probe card having needles for electrically contacting a device under test at a front side of the wafer opposing a back side of the wafer with which the wafer is arranged on the support structure.

17. The test system according to claim 16, wherein the probe card is configured for scanning the front side of the wafer for subsequently testing different devices under test of the wafer.

18. The test system according to claim 16, wherein the needles comprise a force needle for contributing to applying the test current to the electrically contacted device under test and a sense needle for contributing to sensing the sense voltage at the electrically contacted device under test.

19. A method, wherein the method comprises:
arranging a wafer comprising devices under test on a support structure;
applying a test current to the wafer by a force contact arranged at the support structure; and
sensing a sense voltage at the wafer in response to the applied test current by a sense contact arranged at a fixed position of the support structure and being electrically decoupled from the force contact.

20. The method according to claim 19, comprising at least one of the following features:
wherein the method comprises arranging a non-metallized back side of the wafer on the support structure, wherein for example the method comprises guiding the sense contact to penetrate through an oxide layer up to a semiconductor surface on the back side of the wafer;
wherein the method comprises testing chips as the devices under test;
wherein the method comprises testing power semiconductor chips as the devices under test;
wherein the method comprises testing semiconductor chips having a vertical current flow between two opposing main surfaces as the devices under test.
